(19) United States
(12) Patent Application Publication
(10) Pub. No.: US 2012/0187418 A1
(43) Pub. Date: Jul. 26, 2012

(54) SEMICONDUCTOR STRUCTURE AND METHOD FOR MANUFACTURING THE SAME

(76) Inventors: Haizhou Yin, Poughkeepsie, NY (US); Zhijiong Luo, Poughkeepsie, NY (US); Huilong Zhu, Poughkeepsie, NY (US)

(21) Appl. No.: 13/380,964

(22) PCT Filed: Mar. 4, 2011
(86) PCT No.: PCT/CN11/71508

§ 371 Date: Dec. 27, 2011

(30) Foreign Application Priority Data
Jul. 30, 2010 (CN) 201010240547.0

(51) Int. Cl. H01L 29/04; H01L 21/20; H01L 29/36; H01L 29/24; H01L 29/20

(52) U.S. Cl. 257/77; 257/627; 257/76; 257/607; 257/609; 438/478; 257/E21.09; 257/E29.003; 257/E29.104; 257/E29.089; 257/E29.109

(57) ABSTRACT

The present application provides a semiconductor structure and a method for manufacturing the same. The semiconductor structure comprises a semiconductor substrate, a semiconductor fin located on the semiconductor substrate, and an etch stop layer located between the semiconductor substrate and the semiconductor fin, wherein a lateral sidewall of the semiconductor fin is substantially on the Si {111} crystal plane. Since the semiconductor fin exhibits better surface quality and less crystal defects, it is favorable for manufacturing FINFET.

### FIELD OF THE INVENTION

The present invention relates to a semiconductor structure with a fin and a method for manufacturing the same, and specifically, to a semiconductor fin applied in a FINFET and a method for manufacturing the same.

### BACKGROUND OF THE INVENTION

As a result of scaling down of sizes of semiconductor devices, a problem that threshold voltages decrease along with reduction of channel length arises, namely, short-channel effects come up in the semiconductor devices.

In order to alleviate short-channel effects, patent application No. U.S. Pat. No. 6,413,802 disclosed a FINFET formed on SOI, which comprises a channel region formed at the center of a silicon fin and source/drain regions formed respectively at two ends of the silicon fin. Lithography and etching process should be performed sequentially to form the fin in a desired shape. Specifically, a hard mask and a photoresist mask have to be formed on the silicon substrate which is used to form the fin; next, the photoresist mask is patterned by means of lithography; then, a fin in a desired shape is formed on the hard mask and the silicon substrate, by means of etching process using the patterned photoresist as a mask.

It has been already appreciated that the surface quality of a semiconductor fin suffers from adverse effects arising at the etching step. As the semiconductor fin is conventionally formed through dry etching, for example, Reaction Ion Etching (RIE), ion bombardment would easily cause damages to the crystalline structure, which thence results in poor surface quality of the completed fin (i.e. unevenness and high defect density) and finally degrades ability of the gate of the FINFET to control the channel.

Accordingly, it is necessary to provide a semiconductor structure, especially a finlike semiconductor structure which is able to reduce damages arising from etching to the semiconductor structure during its formation.

### SUMMARY OF THE INVENTION

The present invention aims to provide a semiconductor fin with improved surface quality and a method for manufacturing the same.

In one aspect, the present invention provides a semiconductor structure, which comprises a semiconductor substrate, a semiconductor fin located on the semiconductor substrate, and an etch stop layer located between the semiconductor substrate and the semiconductor fin; wherein a lateral sidewall of the semiconductor fin is substantially on the Si { 111 } crystal plane. Preferably, the angle between the lateral sidewall of the semiconductor fin and the Si {111} crystal plane is less than 5°.

Preferably, the semiconductor fin comprises at least one material selected from a group consisting of Si, Ge, GaAs, InP, GaN and SiC.

Preferably, the etch stop layer comprises a highly doped P-type semiconductor or SiGe.

Preferably, the dopant in the P-type semiconductor is at least one doping element selected from a group consisting of B, Al, Ga, In and Tl.

Preferably, the etch stop layer comprises a P-type semiconductor whose doping concentration is higher than 5×10¹⁹/cm³.

Preferably, the etch stop layer comprises a SiGe layer, in which the atomic percent of Ge is 10-30%.

Preferably, the semiconductor substrate comprises a {112} Si substrate.

Preferably, the number of the semiconductor fin is one or more.

In another aspect, the present invention provides a method for manufacturing a semiconductor structure, comprising:

a) epitaxially growing an etch stop layer on a semiconductor substrate;
b) epitaxially growing a semiconductor layer on the etch stop layer;
c) forming a patterned mask layer on the semiconductor layer;
d) removing a portion of the semiconductor layer not covered by the mask layer by means of anisotropic wet etching;

wherein, the wet etching process stops at the upper surface of the etch stop layer, such that a portion of the semiconductor layer covered by the mask layer forms a semiconductor fin, and the lateral sidewalls of the semiconductor fin are substantially on the Si {111} crystal planes.

Preferably, the semiconductor substrate is a {112} Si substrate.

Preferably, the angles between the lateral sidewalls of the semiconductor fin and the Si {111} crystal planes are less than 5°.

Preferably, the step of forming a patterned mask layer comprising:

forming an oxide layer on a semiconductor layer;

forming a patterned photoresist layer on the oxide layer;

removing a portion of the oxide layer not covered by the photoresist layer by way of etching; and

removing the photoresist layer;

wherein, a portion of the oxide layer covered by the photoresist layer forms the patterned mask layer.

Preferably, the etchant used for wet etching comprises one soulution selected from a group consisting of KOH, TMAH, EDP and N₂H₄·H₂O.

Preferably, the etch stop layer comprises a highly doped P-type semiconductor or SiGe.

Preferably, the etch stop layer comprises a P-type semiconductor whose doping concentration is higher than 5×10¹⁹/cm³.

Preferably, the dopant in the P-type semiconductor comprises at least one selected from a group consisting of B, Al, Ga, In and Tl.

Preferably, the etch stop layer comprises a SiGe layer, in which the atomic percent of Ge is 10-30%.

An additional etch stop layer is applied during formation of a semiconductor fin of the present invention, such that dry etching may be replaced by wet etching, which therefore avoids the surface quality being degraded due to ion bombardment arising from dry etching

Since wet etching has excellent selectivity with respect to semiconductor layers, when a semiconductor fin is formed by wet etching, the height of the fin will be equal to the thickness of the semiconductor layer. Therefore, it is possible to control precisely the height of the fin by controlling the thickness of the semiconductor layer.

Besides, anisotropic etching is implemented to the semiconductor layer at the step of wet etching; the lateral sidewalls of the fin are the { 111 } crystal planes that are etched most slowly, which thus avoids occurrence of undercut flaw; and the lateral sidewalls of the fin shall be in good evenness and high crystallization quality as well.

Additionally, after formation of a semiconductor fin of the present invention, ion implantation has to be implemented sequentially to form source/drain regions and selective source/drain extension regions at the two ends of the Si fin. However, ion implantation results in Si amorphization, which requires annealing operation in the following step to transform the amorphous Si into monocrystalline Si through solid-phase epitaxial growth method. Preferably, the lateral sidewalls of the fin in the present invention are { 111 } crystal planes, which then is able to minimize the area of a gravely defected region in the following solid-phase epitaxial growth process.

Meanwhile, the semiconductor substrate used in the present invention is preferably a {112} Si substrate, which is favorable for a faster growth of a SiGe etch stop layer.

Furthermore, the {112} Si substrate used in the present invention produces a greater stress response to the channel positioned in the fin, which therefore improves the carrier mobility.

The semiconductor fin is particularly suitable for manufacturing FINFET, in particular, P-type FINFET or PMOS.

### BRIEF DESCRIPTION OF THE DRAWINGS

FIG. 1a and FIG. 1b illustrate the orientation of a semiconductor fin on a Si substrate according to an embodiment of the present invention.

FIGS. 2 to 7 are cross-sectional views of intermediate structures at respective stages duration formation of a semiconductor fin according to an embodiment of the present invention.

FIG. 8 shows curves of growing speeds of SiGe on Si substrates with different crystal orientations as functions of flow rates of GeH₄ (a reaction material for generating SiGe), in the prior art.

FIG. 9 shows curves of driving currents as functions of angles between channel orientations and fin surface orientations in (111) uniaxial strained Si, in the prior art.

### DETAILED DESCRIPTION OF THE INVENTION

Here below, the present invention will be described in detail in conjunction with accompanying drawings. In respective drawings, same elements are denoted by similar reference numbers. For purpose of clarity, respective portions in the drawings are not drawn to scale.

It should be understood that when a structure of a device is described, such description as a layer or a region is located “on” or “above” another layer or another region may mean that the layer or the region is located directly on the other layer or the other region, or may mean that a further layer or a further region is formed between it and the other layer or the other region. Additionally, if the device is turned over, the said layer or the said region should be located “under” or “below” the other layer or the other region.

Should the situation of being located directly on another layer or another region be described, such expression as “. . . located directly on . . .” or “. . . located on and is adjacent to . . .” is adopted herein.

For a clear understanding of the present invention, plenty of particular details of the present invention, for example, structures, materials, sizes, processing crafts and techniques of devices, will be described here below. However, just as a person skilled in the art can appreciate that the present invention may also be implemented without these particular details. For example, semiconductor materials of a substrate and a fin may be selected from group IV semiconductors, for example, Si or Ge, or from group III-V semiconductors, for example, GaAs, InP, GaN, SiC, or stacked layers of abovementioned semiconductor materials.

Additionally, when a crystal plane or a crystal orientation is described here below, it is represented using a family of crystal planes or a family of crystal orientations. For example, the specific crystal orientations [110] and [1 1̅0] indicate two directions perpendicular to each other; whereas, ascribing to symmetry of Si crystal, these two specific crystal orientations may be uniformly represented by the <110> crystal orientation family. Since the property of symmetry of Si crystal is widely known in the art, the expression “<110> crystal orientation is perpendicular to <110> crystal orientation” may be interpreted as “a specific [110] crystal orientation is perpendicular to another specific ^{[}1 1̅0] crystal orientation or as a similar directional relationship.

Herein, the term “etch stop layer” indicates such a layer that is etched slower than a semiconductor layer to be etched away. Ascribing to the difference between the etching speeds of the etch stop layer and the semiconductor layer, the semiconductor layer may be removed selectively. The etch stop layer may be composed of a highly doped (e.g. doping concentration is higher than 5×10¹⁹/cm³) P-type semiconductor or SiGe, wherein the dopant may be at least one doping element selected from a group consisting of B, Al, Ga, In and Tl.

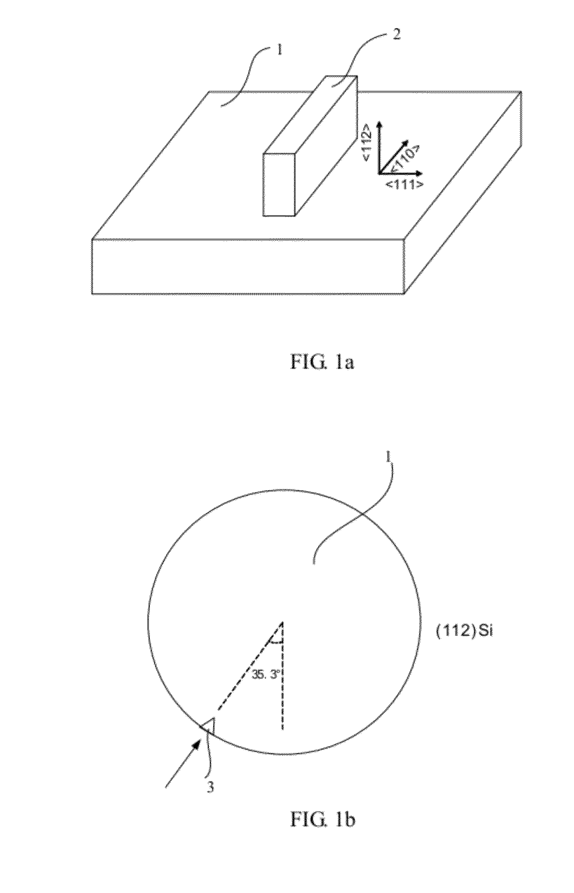

Semiconductor fins provided by embodiments of the present invention are suitable for manufacturing FINFET, particularly, P-type FINFET or PMOS. For brevity's sake, a semiconductor fin for P-type FINFET or PMOS is exemplarily referred to whenever it is mentioned here below. Of course, a person skilled in the art should appreciate that semiconductor fins according to embodiments of the present invention are also applicable for any other conventional semiconductor device. As shown in FIG. 1a, the present invention aims to form a semiconductor fin 2 on a semiconductor substrate 1. For purpose of illustration only, both the semiconductor substrate 1 and the fin 2 are consisted of Si. The fin 2 may be formed on the (112) surface of the semiconductor substrate 1 and be formed by way of epitaxially growing a semiconductor layer and etching the same semiconductor layer. The epitaxial growth method may be, for example, Molecular Beam Epitaxy (MBE). The fin 2 extends along the Si <112> orientation, and its lateral sidewalls are substantially on the Si {111} crystal planes.

As shown in FIG. 1b, in order to form a fin 2, which extends along Si <112> orientation and whose lateral sidewalls are {111} crystal planes, in the following lithography and etching steps, a pattern direction has to be determined according to the position of a notch 3. Herein, in order to obtain the orientation of fin 2 as illustrated in FIG la, the position of the notch 3 of the Si wafer 1 is typically arranged to denote the Si <111> crystal orientation. In the event that the notch 3 of the Si wafer 1 does not initially denote the <111> crystal orientation, the Si wafer 1 has to be rotated by an angle as appropriate. For example, in the event that the notch 3 of the Si wafer 1 denotes initially the <110> crystal orientation, the Si wafer 1 has to be rotated clockwise by about 35.3° around its center as the rotation axis, such that the position of the notch 3 of the Si wafer 1 shall be changed to denote the <111> crystal orientation.

In fact, the lateral sidewalls of a fin are likely to deviate from the Si {111 } crystal planes due to process deviations. For example, aforesaid rotation angle may have a deviation of a certain extent. However, as the inventor has noted, an optimized surface quality shall still be achieved in a fin, when the angles between the lateral sidewalls of the fin and Si {111 } crystal planes are less than 5°.

FIG. 2 to FIG. 7 illustratively show cross-sectional views of intermediate structures at respective stages in the formation of a semiconductor fin before the step of solid-phase epitaxial growth.

A method according to an embodiment of the present invention is started from a monocrystalline Si substrate 10.

As shown in FIG. 2, a SiGe layer 11 (functions as an etch stop layer) of a thickness about 5-20 nm, in which Ge content is as much as 10%-30% (the percentage of Ge atoms, i.e., the percentage of the number of Ge atoms against the number of total atoms), and a Si layer 12 of a thickness about 20-70 nm are epitaxially grown sequentially on the surface of the Si substrate 10 by means of conventional deposition processes, for example, PVD, CVD, Atom Layer Deposition, sputtering, etc. Here, the epitaxial growth process is mainly applied to control the thickness of the Si layer 12 that is to be shaped into a fin. At the following steps, the fin is to be formed by way of patterning the Si layer 12; the thickness of the Si layer 12 may be determined in dependence on the demand of the height of the fin in designing a device.

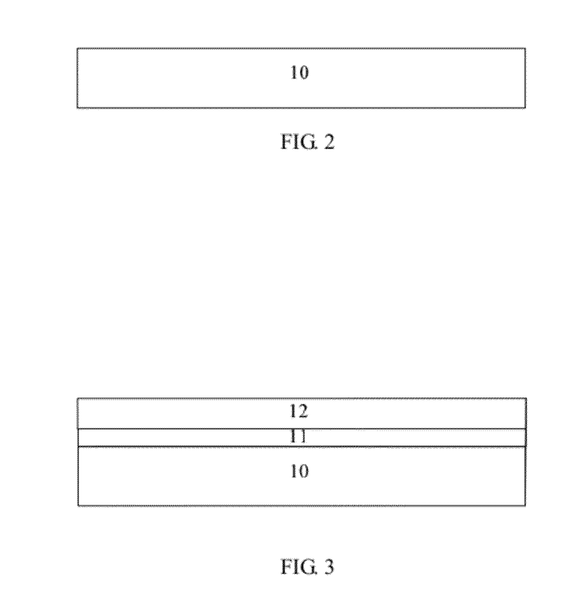

As shown in FIG. 3, a silicon oxide layer 13 and a nitride layer 14, which will function as a hard mask and a protection layer, are formed on the surface of the Si layer 12.

The surface of the Si layer 12 may be transformed to a silicon oxide layer 13 by means of thermal oxidation. Alternatively, the silicon oxide layer 13 may be formed by means of aforesaid conventional deposition processes. The thickness of the silicon oxide layer 13 is about 5 nm.

A nitride layer 14 (e.g. Si₃N₄) with a thickness of about 10 nm is formed on the silicon oxide layer 13 by means of aforesaid conventional deposition technique.

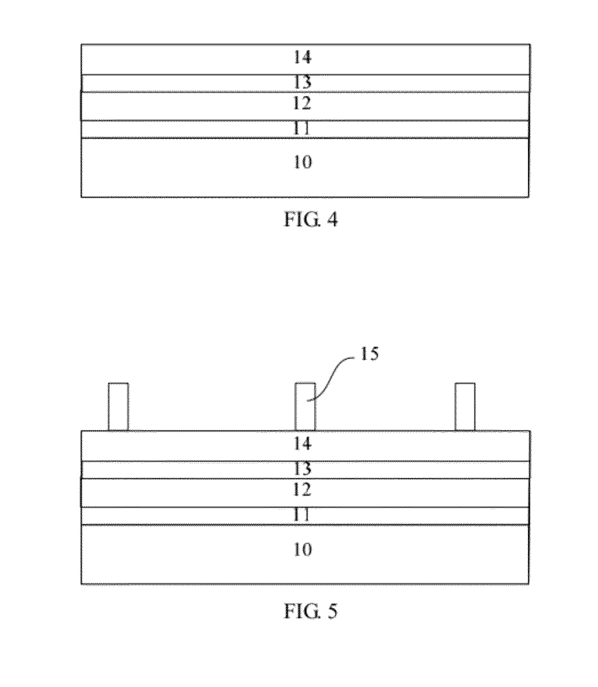

As shown in FIG. 4, a photoresist layer is coated on the surface of the nitride layer 14; next, a patterned photoresist mask 15 is formed by means of lithography consisting of exposing and developing processes.

Alternatively, the photoresist mask 15 may be formed by means of E-beam lithography or other method as appropriate.

A bar within the photoresist mask 15 corresponds to the shape of a Si fin, which therefore determines the extending direction, length and width of the fin.

As shown in FIG. 5, the portions of the Si₃N₄ layer 14 and the SiO₂ layer 13, which are not covered by the patterned photoresist mask 15, are removed downwards sequentially, by means of a conventional wet etching method that makes use of an etching solution, or by means of dry etching, for example, Ion Milling Etching, Plasma Etching, Reaction Ion Etching (RIE) and Laser Engraving. Next, the photoresist mask may be removed through resolving in a solution or an ashing process.

The above step transfers the pattern of the photoresist mask 15 to the Si₃N₄ layer and the SiO₂ layer, which thence form hard masks.

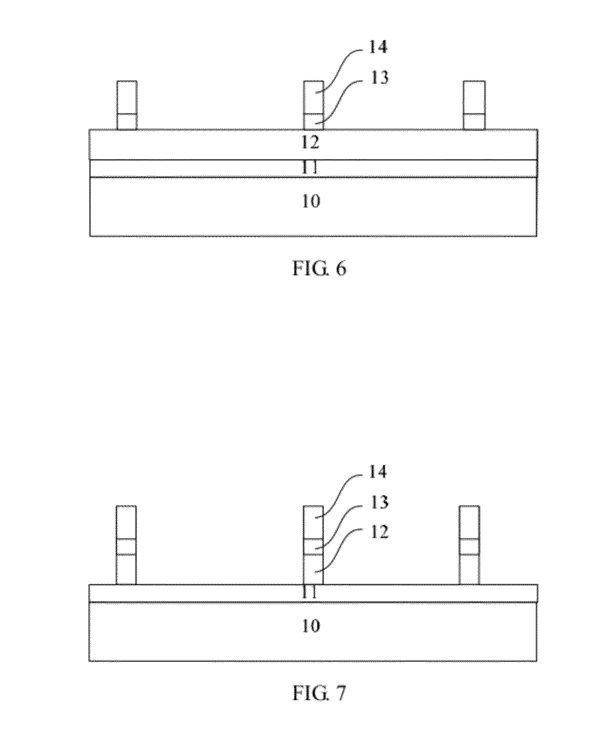

As shown in FIG. 6, Si is removed selectively by means of a conventional wet etching method, in which an etching solution is used, which etching is stopped on the upper surface of the SiGe layer 11, such that a Si fin is formed in the Si layer 12.

Because wet etching exhibits excellent selectivity against SiGe and Si, as a result, the thickness of the Si fin is equal to the thickness of the Si layer 12. It is easy to control the thickness of a fin to be finally formed, since the thickness of the formed Si layer 12 is controlled at the foresaid deposition step (i.e. the epitaxial growth process thereof).

In order to form a fin by means of wet etching, the present invention makes use of an additional etch stop layer, and the height of the fin to be formed is equal to the thickness of the semiconductor layer from which it is formed, such that the height of the fin may be controlled precisely with the thickness of the semiconductor layer. Favorably, a fin with a desired thickness may be formed ascribing to the excellent selectivity of wet etching, since dry etching is completely replaced by wet etching, the problems such as flaw in surface quality caused by particle bombardment and collision occurring at dry etching are restrained accordingly.

Anisotropic etching solutions for Si widely known in the art may be applied in the present invention; for example, KOH, TMAH, EDP, N₂H₄·H₂O, etc.

In the event that KOH or EDP or the like is used as an etching solution, the material such as a highly doped P-type semiconductor or SiGe may function as an etch stop layer. The dopant in the highly doped P-type semiconductor may be selected from B, Al, Ga, In, Tl or the like, which is able to exhibit an excellent etching selectivity against Si. Aforesaid anisotropic etching solutions etch at different speeds on respective Si crystal planes; the etching speed on the Si {111 } crystal plane is at least one order of magnitude less than that on other crystal planes, therefore, wet etching further exhibits good selectivity to different Si crystal planes.

For the fin orientation as shown in FIG la, the etching speed along the vertical direction (i.e. Si <112> crystal orientation) is obviously faster than that along the lateral direction (i.e. Si <111> crystal orientation). As such, undercut occurring in the fin is suppressed, and the lateral sidewalls of the fin become the {111 } crystal planes that are exposed due to etching.

Since both the top surface and lateral sidewall surfaces of the fin exhibit optimized evenness and crystalline quality, thus the fin is particularly suitable for manufacturing a double-gate FINFET.

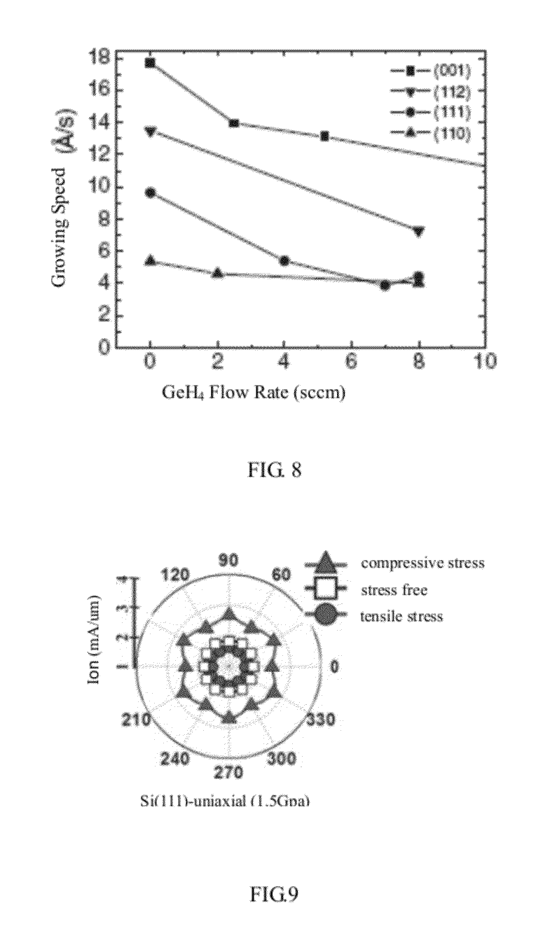

It is noteworthy that, according to an embodiment of the present invention, when SiGe functioning as an etch stop layer shall be epitaxially grown on a substrate (as shown in FIG. 2), using {112} Si substrate is favorable for faster growth of a SiGe etch stop layer, as compared to using a Si substrate with other orientations (e.g. a {110} Si substrate). FIG. 8 illustrates curves of growing speeds of SiGe on Si substrates with different crystal orientations as functions of flow rates of GeH₄ (a reaction material for generating SiGe). As clearly shown in FIG. 8, in case that other conditions are the same, SiGe grows faster on a {112} Si substrate than on any other substrate, for example, on a {110} Si substrate.

Besides, for a FINFET semiconductor device, the channel is located in its fin. When the {112} Si substrate of the present invention and the comparison {110} Si substrate are used respectively, the orientations of the lateral sidewall surfaces of the fins may be the same, i.e., both are { 111 } crystal plane, yet the orientations of channels formed in the fins are nonetheless different: {112} Si substrate corresponds to a channel in a [110] orientation (in the present invention); while {110} Si substrate corresponds to a channel in a [112 ] orientation (in the comparison example); channels in different orientations may bring forth different effects on the performance of the semiconductor device. FIG. 9 shows curves of driving currents as functions of angles between channel orientations and fin surface orientations in (111) uniaxial strained Si. Those skilled in the art are able to calculate an angle between a channel orientation and a surface orientation of a fin by means of the conventional vector cross product method. For uniaxial strained Si, on the Si (111) crystal plane, the [110] orientation (in the present invention) corresponds to an angle of about 35°, and the [112] orientation (in the comparison example) corresponds to an angle of about 20°. According to the curves in FIG. 9, the channel orientation in the present invention corresponds to a relatively greater driving current. In other words, in a PMOS semiconductor device, using a {112} Si substrate of the present invention shall produce a greater stress response to the channel in a fin, which thence improves hole mobility, as compared to the {110} Si substrate used in the comparison example. Therefore, the present invention is not limited to the embodiments given herein. Any modification or alternation obviously known to those skilled in the art shall be in the scope of the present invention.

What is claimed is:

1. A semiconductor structure, comprising a semiconductor substrate, a semiconductor fin located on the semiconductor substrate, and an etch stop layer located between the semiconductor substrate and the semiconductor fin, wherein a lateral sidewall of the semiconductor fin is substantially on the Si {111} crystal plane.

2. The semiconductor structure of claim 1, wherein the semiconductor substrate is a {112} Si substrate.

3. The semiconductor structure of claim 1, wherein the angle between the lateral sidewall of the semiconductor fin and the Si {111} crystal plane is less than 5².

4. The semiconductor structure of claim 1, wherein the semiconductor fin comprises at least one material selected from a group consisting of Si, Ge, GaAs, InP, GaN, and SiC.

5. The semiconductor structure of claim 1, wherein the etch stop layer comprises a highly doped P-type semiconductor or SiGe.

6. The semiconductor structure of claim 5, wherein the dopant in the P-type semiconductor is at least one doping element selected from a group consisting of B, Al, Ga, In, and TI.

7. The semiconductor structure of claim 5, wherein the etch stop layer comprises a P-type semiconductor whose doping concentration is higher than 5×10¹⁹/cm³.

8. The semiconductor structure of claim 5, wherein the etch stop layer comprises a SiGe layer, in which the atomic percent of Ge is 10-30%.

9. The semiconductor structure of claim 1, wherein the number of the semiconductor fin is one or more.

10. The semiconductor structure of claim 1, wherein the channel in the semiconductor fin is in the direction of <110> orientation.

11. A method for manufacturing a semiconductor structure, comprising:
a) epitaxially growing an etch stop layer on a semiconductor substrate;
b) epitaxially growing a semiconductor layer on the etch stop layer;
c) forming a patterned mask layer on the semiconductor layer;
d) removing a portion of the semiconductor layer not covered by the mask layer by means of anisotropic wet etching,
wherein, the wet etching process stops at the upper surface of the etch stop layer, such that a portion of the semiconductor layer covered by the mask layer forms a semiconductor fin, and a lateral sidewall of the semiconductor fin is substantially on the Si {111} crystal plane.

12. The method of claim 11, wherein the semiconductor substrate is a {112} Si substrate.

13. The method of claim 11, wherein the angle between the lateral sidewall of the semiconductor fin and Si {111} crystal plane is less than 5².

14. The method of claim 11, 12 or 13, wherein the step of forming a patterned mask layer comprising:
forming an oxide layer on the semiconductor layer;
forming a patterned photoresist layer on the oxide layer;
removing a portion of the oxide layer not covered by the photoresist layer by way of etching; and
removing the photoresist layer,
wherein, a portion of the oxide layer covered by the photoresist layer forms the patterned mask layer.

15. The method of claim 11, wherein an etching solution used in the wet etching comprises one solution selected from a group consisting of KOH, TMAH, EDP, and N₂H₄·H₂O.

16. The method of claim 11, wherein the etch stop layer comprises a highly doped P-type semiconductor or SiGe.

17. The method of claim 16, wherein the etch stop layer comprises a P-type semiconductor whose doping concentration is higher than 5×10¹⁹/cm³.

18. The method of claim 16, wherein the dopant in the P-type semiconductor comprises at least one material selected from a group consisting of B, Al, Ga, In, and TI.

19. The method of claim 16, wherein the etch stop layer comprises a SiGe layer, in which the atomic percent of Ge is 10-30%.

20. The method of claim 11, wherein the channel in the semiconductor fin is in the direction of <110> orientation.
